(19) United States
(12) Patent Application Publication
(10) Pub. No.: US 2015/0340148 A1
(43) Pub. Date: Nov. 26, 2015

(54) INDUCTOR AND METHOD OF FORMING AN INDUCTOR

(71) Applicant: Infineon Technologies AG, Neubiberg (DE)

(72) Inventors: Bernd Landgraf, St. Martin (AT); Maximilian Hofer, Hartberg (AT)

(73) Assignee: Infineon Technologies AG, Neubiberg (DE)

(21) Appl. No.: 14/285,845

(22) Filed: May 23, 2014

(51) Int. Cl. H01F 27/28; H01F 41/04

(52) U.S. Cl. CPC H01F 27/2804; H01F 41/041; H01F 2027/2809

(57) ABSTRACT

An inductor for a semiconductor device is provided, which may include: a plurality of structured metallization layers, wherein the plurality of structured metallization layers includes at least a first metallization layer, a second metallization layer disposed over the first metallization layer, a third metallization layer disposed over the second metallization layer, and a fourth metallization layer disposed over the third metallization layer; wherein a portion of the first metallization layer and a portion of the fourth metallization layer form a first coil; wherein a portion of the second metallization layer and a portion of the third metallization layer form a second coil; and wherein the second coil is arranged within the inner space defined by the first coil.

### TECHNICAL FIELD

Various embodiments relate generally to an inductor and to a method of forming an inductor.

### BACKGROUND

As for example shown in FIG. 11, inductors 1 for semiconductor devices may be formed by planar coils M1 to M4, i.e. by conducting, electrically connected segments that are coiled up within a plane that is parallel to main surfaces of the semiconductor device. An inductance L may be given by L˜N²×A, wherein N is the number of turns of the coil (also referred to as the number of loops), and A is the effective area. In such an inductor 1, the number of turns may be limited, and the effective area may be restricted.

### SUMMARY

An inductor for a semiconductor device is provided, which may include: a plurality of structured metallization layers, wherein the plurality of structured metallization layers includes at least a first metallization layer, a second metallization layer disposed over the first metallization layer, a third metallization layer disposed over the second metallization layer, and a fourth metallization layer disposed over the third metallization layer; wherein a portion of the first metallization layer and a portion of the fourth metallization layer form a first coil; wherein a portion of the second metallization layer and a portion of the third metallization layer form a second coil; and wherein the second coil is arranged within the inner space defined by the first coil.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a coil of an inductor in accordance with various embodiments;

FIGS. 1B, 1C and 1D show schematic views of configurations of regions of structured metallization layers in accordance with various embodiments;

FIG. 2 shows a coil of an inductor in accordance with various embodiments;

FIGS. 3A and 3B show a schematic perspective view and a schematic cross section of an inductor in accordance with various embodiments;

FIG. 4 shows a schematic cross section of an inductor in accordance with various embodiments;

FIG. 5 shows a schematic view of one end of an inductor in accordance with various embodiments;

FIG. 6 shows a schematic view of one end of an inductor in accordance with various embodiments;

FIG. 7 shows a schematic diagram of a method of forming an inductor for a semiconductor device;

FIG. 8A to FIG. 8I show a process flow for a method of forming an inductor for a semiconductor device;

FIG. 9 shows a schematic diagram of a method of forming an inductor for a semiconductor device;

FIG. 10A to FIG. 10E show a process flow for a method of forming an inductor for a semiconductor device; and

FIG. 11 shows a schematic perspective view of an inductor.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be constructed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

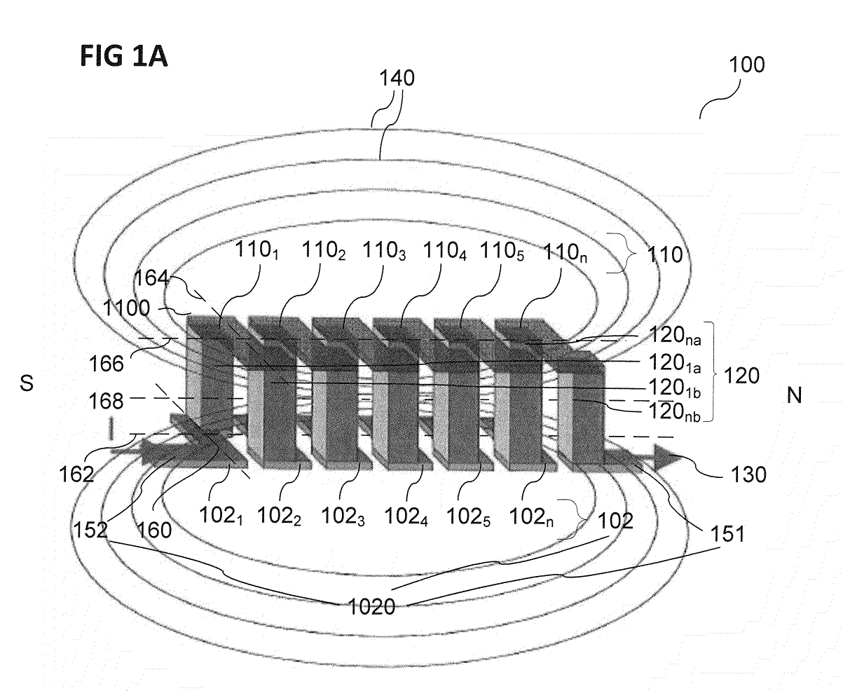

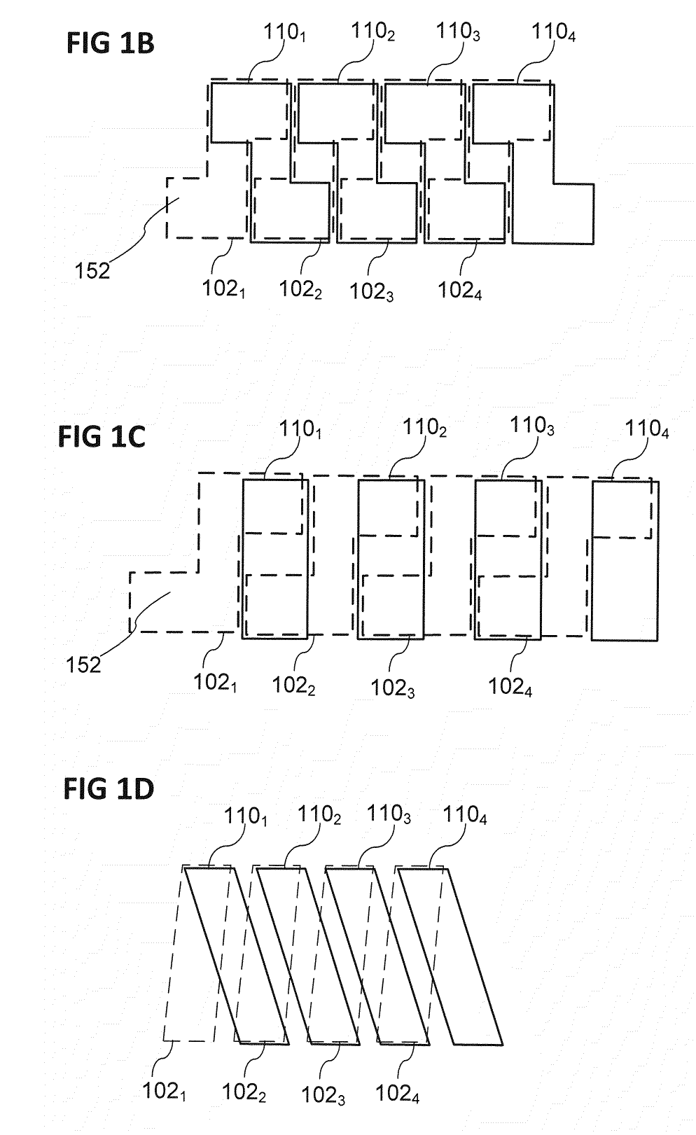

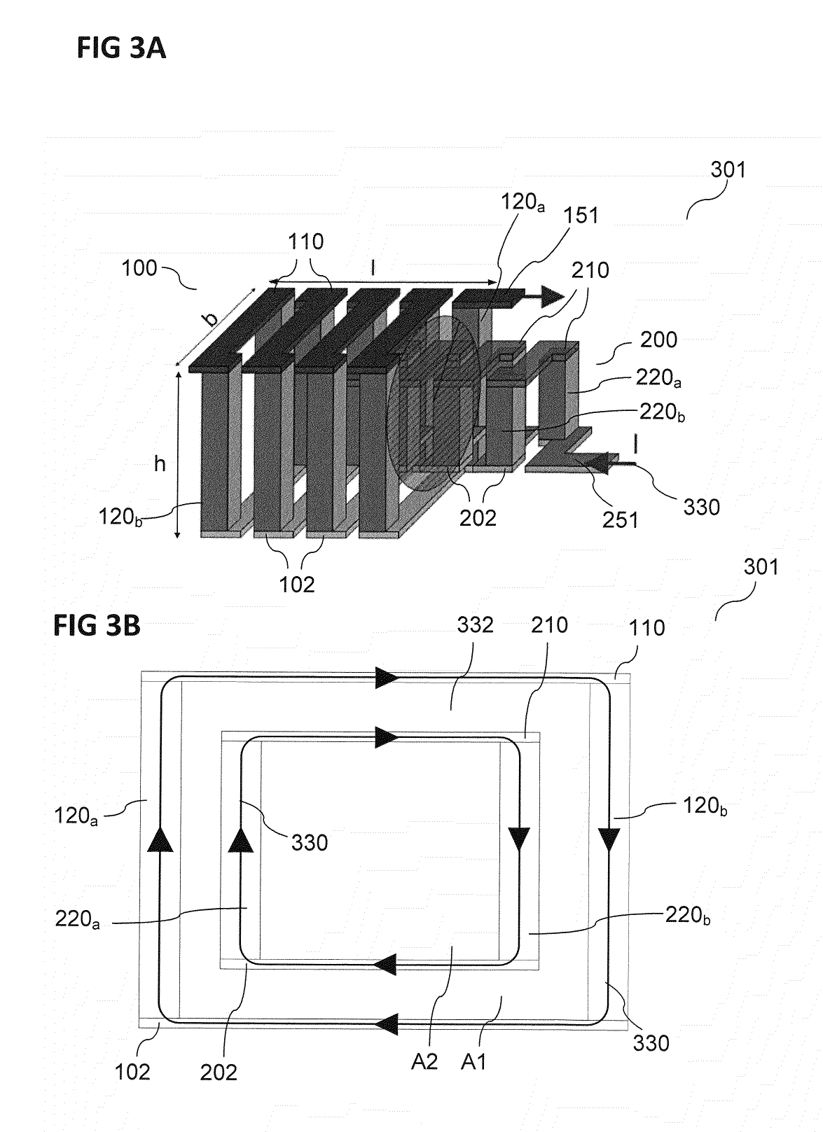

FIG. 1A shows a first coil 100 of an inductor in accordance with various embodiments. By way of example, the first coil 100 may be included in an inductor 301 as shown in FIG. 3.

In various embodiments, the inductor may be included in or be part of a semiconductor device or an integrated monolithic circuit.

The first coil 100 may, in various embodiments, include a first metallization layer 1020. The first metallization layer 1020 may be a structured metallization layer. A portion of the first metallization layer 1020 may be structured to form a plurality of regions 102₁, 102₂, 102₃, 102₄, . . . 102ₙ. In situations where it is not important to know which specific region of the first metallization layer 1020 is being referred to, the index may be omitted, and either an individual region of the first metallization layer 1020 may for example be referred to as “the/one/a region 102 of the first metallization layer”, or all the regions 102₁, 102₂, 102₃, 102₄, . . . 102ₙ of the first metallization layer 1020 or a subset of those regions may for example be referred to as “the/some regions 102 of the first metallization layer”.

The first metallization layer 1020 may at least include the regions 102. In various embodiments, the first metallization layer 1020 may additionally include one or more electrical connectors 151, 152. In various embodiments, the structured first metallization layer 1020 may also include further metallization structures (not shown) of the semiconductor device.

In a plane of the first metallization layer 1020, the regions 102 may be separated from each other by electrically insulating material. The first metallization layer 1020 may further be electrically insulated from adjacent conducting or semiconducting layers or structures by means of insulation layers or regions, except in coupling regions where an electrical contact is desired. In the coupling regions, an electrical contact may be established, for example by removing insulating material of the insulation layer in the coupling region, and/or by replacing the insulating material by conductive material in the coupling region.

The regions 102 may, in various embodiments, have a shape that is elongated, with a long axis 160 in the plane of the first metallization layer and in a direction in which the region 102 is elongated. The regions 102 may be arranged in parallel with respect to their long axes 160 and next to each other in a band- or ladder-like configuration, as shown in FIG. 1A to FIG. 1D. Thus the arrangement of regions 102, also referred to as the portion of the first metallization layer, may also have a long axis 162, which does not coincide with the long axes 160 of the regions 102, but may rather be defined by a line connecting mid points of the regions 102. Apart from being elongated, the regions 102 may have any shape that allows for an area-efficient parallel arrangement of the regions 102 and that, in combination with vias 120 and regions 110 of a fourth metallization layer, allows for electrical connections to be established between the regions 102, the vias 120, and the regions 110 in such a way that an electric current (also referred to as “current”) can be propagated helically from one end of the parallel arrangement of regions 102/110 to the other end of the parallel arrangement of regions 102/110. Exemplary configurations of regions 102/110 are shown in FIG. 1B to FIG. 1D. In various embodiments, all regions 102 may for example have the same shape, such that they can be tiled (separated by the insulator). In various embodiments, the regions 102 may for example be S-shaped (like in FIG. 1A) or Z-shaped (wherein the ends of the S- or Z-shaped regions may be oriented in parallel to the long axes 160, 162, like in FIG. 1A, or orthogonal to them (not shown)). The regions 102 may also for example be rhomboid or rectangular. See also below in the description of regions 110 for a more detailed description of possible shapes and arrangements of the regions, which also applies to the regions 102.

In various embodiments, some of the regions 102 may have a different shape than some others of the regions 102.

In various embodiments, a distance between adjacent regions 102 may be in a range from about 0.2 μm to about 2 μm, for example from about 0.5 μm to about 1.5 μm. A length of the regions 102 along each of their long axes 160 may be in a range from about 1 μm to about 15 μm, for example from about 3 μm to about 8 μm. A width of the regions 102 in a direction of the axis 162, or/and in a direction of a narrowest dimension of each region 102, may be in a range from about 0.5 μm to about 3 μm, for example from about 1 μm to about 2 μm. A thickness of the regions 102, and hence a thickness of the first metallization layer, may be in a range from about 20 nm to about 2 μm, for example from about 50 nm to about 400 nm.

In various embodiments, the regions 102 of the first metallization layer may include any conductive material, for example any conductive material that is used for forming metallization layers in semiconductor devices. The first metallization layer (and hence the regions 102) may for example include Ag, Pt, Au, Mg, Al, Ba, In, Ag, Au, Mg, Ca, Sm or Li, (Cu) or any combination or alloy of those metals.

The first coil 100 may, in various embodiments, include a fourth metallization layer 1100. The fourth metallization layer 1100 may be a structured metallization layer. A portion of the fourth metallization layer 1100 may be structured to form a plurality of regions 110₁, 110₂, 110₃, 110₄, . . . 110ₙ of a fourth metallization layer. In situations where it is not important to know which specific region of the fourth metallization layer is being referred to, the index may be omitted, and either an individual region of the fourth metallization layer may for example be referred to as “the/one/a region 110 of the fourth metallization layer”, or all the regions 110₁, 110₂, 110₃, 110₄, . . . 110ₙ of the fourth metallization layer or a subset of those regions may for example be referred to as “the/some regions 110 of the fourth metallization layer”.

The fourth metallization layer 1100 may at least include the regions 110. In various embodiments, the fourth metallization layer 1100 may additionally include one or more of the electrical connectors 151, 152. In various embodiments, the fourth metallization layer 1100 may also include further metallization structures (not shown) of the semiconductor device.

In a plane of the fourth metallization layer, the regions 110 may be separated from each other by electrically insulating material. The fourth metallization layer 1100 may further be electrically insulated from adjacent conducting or semiconducting layers or structures by means of insulation layers or regions, which may include or consist of electrically insulating material, except in coupling regions where an electrical contact is desired. In those coupling regions, an electrical contact may be established, for example by removing insulating material of the insulation layer in the coupling region, and/or by replacing the insulating material by conductive material in the coupling region.

The regions 110 may, in various embodiments, have a shape that is elongated, with a long axis 164 in the plane of the fourth metallization layer 1100 and in a direction in which the region 110 is elongated. The regions 110 may be arranged in parallel with respect to their long axes 164 and next to each other in a band- or ladder-like configuration, as shown in FIG. 1A. Thus the arrangement of regions 110—the portion of the fourth metallization layer—may also have a long axis 166, which does not coincide with the long axes 164 of the regions 110, but may rather be defined by a line connecting mid points of the regions 110. Apart from being elongated, the regions 110 may have any shape that allows for an area-efficient parallel arrangement of the regions 110 and, in combination with vias 120 and the regions 102 of first metallization layer, allows for electrical connections to be established between the regions 110, the vias 120, and the regions 102 in such a way that a current can be propagated helically from one end of the parallel arrangement of regions 102/110 to the other end of the parallel arrangement of regions 102/110. In various embodiments, all regions 110 may for example have the same shape, such that they can be tiled (separated by the insulating material). In various embodiments, the regions 110 may for example be Z-shaped (like in FIG. 1A) or S-shaped (wherein the ends of the S- or Z-shaped regions may be oriented in parallel to the long axes 160, 162, like in FIG. 1A, or orthogonal to them (not shown)). The regions 110 may further for example be rhomboid or rectangular. In various embodiments, as for example shown in FIG. 1A, the regions 102 may be shaped differently than the regions 110. For example, the regions 102 may be S-shaped, and the regions 110 may be Z-shaped, or vice versa, or the regions 102 may be more pronouncedly S- or Z-shaped, while the regions 110 are rectangular or rhomboid (or vice versa).

In various embodiments, some of the regions 110 may have a different shape than some others of the regions 110.

FIG. 1B to FIG. 1D schematically show various arrangements of the regions 102 and the regions 110 as seen vertically from above (also referred to as a vertical projection) if the coil was arranged like the first coil 100 in FIG. 1A (i.e., with the regions 110 on top of the regions 102, e.g. the regions 110 above a plane of the paper and the regions 102 below). The slight horizontal and vertical shift of the outlines of the regions 102 and the regions 110 was applied to facilitate the recognition of the individual regions, and not to represent physical reality, even though such shifts may occur due to manufacturing uncertainties or may, in various embodiments, even be intended. As shown in FIG. 1B to FIG. 1D, in various embodiments, a region 110ₓ (where x may be any index of the regions 110 present in the first coil, except 1 or n) may at its one end overlap in the vertical projection with the region 102ₓ, and at its other end with the region 102ₓ₊₁.

In various embodiments, a current entering the first coil 100 from the left (through a bottom region 102) would in its flow first reach an overlap area between regions 102 and 110 shown on top of FIG. 1B, FIG. 1C or FIG. 1D, respectively, flow through the via 120 (not shown) to the region 110, towards an overlap area between region 110 and region 102 shown in the bottom of FIG. 1B, FIG. 1C or FIG. 1D, respectively. The current would thereby have flowed through one loop of the first coil 100 formed by one region 102, two vias and one region 110, and would have done so in a clockwise direction if seen from the entry point of the current. If the current was a conventional current, a south magnetic pole would form at the entry point of the current, and a north magnetic pole at an exit point of the current (as also shown in FIG. 1A).

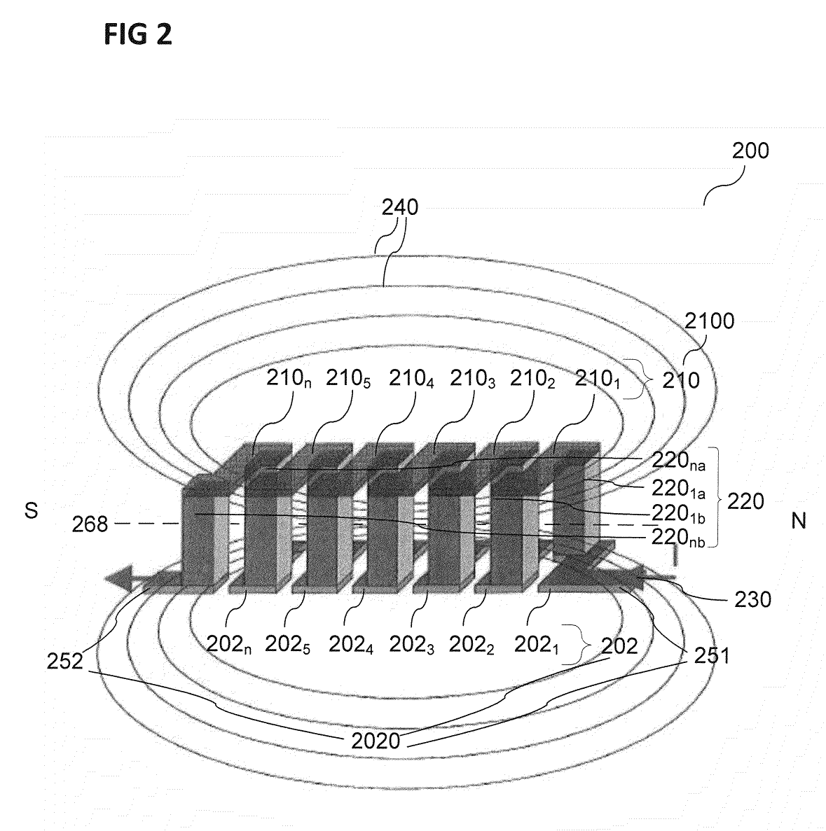

In various embodiments, if mirrored configurations to the ones shown in FIG. 1A to FIG. 1D were assumed (see for example FIG. 2, which however depicts a current entering from the right), a current entering the coil from the left (through a bottom region) would in its flow first reach an overlap area between regions 102 and 110 that would then be located in the bottom of the hypothetical mirrored figure, flow through the via 120 (not shown) to the region 110, towards an overlap area between region 110 and region 102 that would then be located at the top of the hypothetical mirrored figure. The current would thereby have flowed through one loop of the coil, and would have done so in a counter-clockwise direction if seen from the entry point of the current. If the current was a conventional current, a north magnetic pole would form at the entry point of the current, and a south magnetic pole at an exit point of the current (see also FIG. 2 for a comparison with a current entering from the right, but also with the north pole N forming at the entry point of the current 230).

In various embodiments, the shapes, sizes and total numbers of the regions 102 and 110 may be selected in accordance with various requirements, for example to obtain a specific inductance, to cover the smallest area in the respective metallization layers with which a desired inductance can be realized, to allow for a maximum number of loops, to allow for a high throughput of current, and the like. In various embodiments, a length l (for the first coil 100 also referred to as l₁) of the first coil 100, i.e. a size of the first coil 100 along its long axis 168 (indicated in FIG. 3A, defined by a line running through mid-points of all loops, which means that the line would even then be referred to as the long axis of the coil 100 if the length l of the first coil 100 was smaller than one or both of the other dimensions of the coil 100), may for example be in a range from about 1 μm to about 50 μm, for example from about 5 μm to about 20 μm, for example around 10 μm.

A width b (for the first coil 100 also referred to as b₁ and indicated in FIG. 3A) of the first coil 100, i.e. a size of the first coil 100 in a direction orthogonal to its length and within a plane in or parallel to the first metallization layer 1020 or second metallization layer 1100, may be in a range from about 0.1 μm to about 30 μm, for example from about 1 μm to about 10 μm, for example around 5 μm.

A height h (for the first coil 100 also referred to as h₁ and indicated in FIG. 3A) of the first coil 100, i.e. a size of the first coil 100 in a direction orthogonal to its length and orthogonal to the first metallization layer 1020 or second metallization layer 1100, may be in a range from about 0.1 μm to about 30 μm, for example from about 1 μm to about 10 μm, for example around 5 μm.

In various embodiments, a distance between adjacent regions 110 may be in a range from about 0.2 μm to about 2 μm, for example from about 0.5 μm to about 1.5 μm. A length of the regions 110 along each of their long axes 164 may be in a range from about 1 μm to about 15 μm, for example from about 3 μm to about 8 μm. A width of the regions 110 in a direction of the axis 166, or/and in a direction of a narrowest dimension of each region 110, may be in a range from about 0.5 μm to about 3 μm, for example from about 1 μm to about 2 μm. A thickness of the regions 110, and hence a thickness of the fourth metallization layer 1100, may be in a range from about 20 nm to about 2 μm, for example from about 50 nm to about 400 nm.

In various embodiments, the regions 110 of the fourth metallization layer 1100 may include any conductive material, for example any conductive material that is used for forming metallization layers in semiconductor devices. The fourth metallization layer 1100 (and hence the regions 110) may for example include Ag, Pt, Au, Cu, Mg, Al, Ba, In, Ag, Au, Ca, Sm or Li, or any combination or alloy of those metals.

The first and fourth metallization layers 1020, 1100 may be formed by means of any suitable method, for example by means of deposition, for example by means of chemical vapor deposition (CVD), physical vapor deposition (PVD), or electrochemical deposition.

In various embodiments, the metallization layers 1020, 1100 may be structured during the formation. In various embodiments, the formation of the metallization layer 1020, 1100 may be followed by a structuring of the metallization layer 1020, 1100, for example by means of photolithography.

The first coil 100 may, in various embodiments, include a plurality of vias 120₁ₐ, 120₂ₐ, 120₃ₐ, . . . 120ₙₐ and 120_{1b}, 120₂ₕ, 120₃ₕ, . . . 120_{nb}, wherein the vias 120 indexed with “a” may form a first row of vias 120ₐ, and the vias 120 indexed with “b” may form a second row of vias 120_{b}. In situations where it is not important to know which specific via is being referred to, the index number and/or the index letter may be omitted, and either an individual via may for example be referred to as “the/one/a via 120”, “the/one/a via 120ₐ”, “the/one/a via 120_{b}”, or all the vias 120₁ₐ, 120₂ₐ, 120₃ₐ, 120₄ₐ, . . . 120ₙₐ or a subset of all the vias 120₁ₐ, 120₂ₐ, 120₃ₐ, 120₄ₐ, . . . 120ₙₐ may for example be referred to as “the/some vias 120”, “the/some vias 120ₐ” or “the/some vias 120_{b}”, respectively.

Each via 120 may be electrically coupled, for example electrically connected, either to one region 102 and to one region 110, or to one of the regions 102 or 110, respectively, and to one of the electrical connectors 151, 152, wherein the electrical connectors 151, 152 may be used for electrically coupling to the first coil 100. In various embodiments, the first coil 100 may for example be electrically coupled to other parts of the inductor, or the first coil 100 may be electrically coupled to a circuit, a via, a power source, a die, or the like (not shown), by means of the electrical connectors 151, 152. The electrical connectors 151, 152 may in that case also be referred to as “external connectors”.

In various embodiments, as for example shown in FIG. 1A, each via 120a of the row of vias 120a may be arranged at one end of the elongated regions 102 and 110, respectively, and may be electrically coupled, for example electrically connected, to the ends of the regions 102 and 110, respectively. Each via 120b of the row of vias 120b may be arranged at the other end of the elongated regions 102 and 110, respectively, and may be electrically coupled, for example electrically connected, to the other ends of the regions 102 and 110, respectively. In various embodiments, where the regions 102 and 110 may be S- or Z-shaped, the vias may be arranged on parts of the ends of the regions 102 and 110, respectively, wherein the parts of the ends of the regions 102 and 110 extend parallel to each other, for example parallel or orthogonal to the axes 162 or 166, respectively. Such an arrangement may allow for an easy construction of the electrical connection between the elongated regions 102, 110, and/or for a large overlap area between the regions 102 and 110, such that the vias 120 may have relatively large cross sections allowing for a relatively high current.

The vias 120 may, in various embodiments, be formed through the insulating material arranged between the first metallization layer and the fourth metallization layer, for example by means of etching of openings in the insulating material and subsequent filling of the openings with conductive material. In various embodiments, the conductive material may be any conductive material, in various embodiments any conductive material that is typically used in the production of vias in semiconductor devices. The vias 120 may for example include Ag, Pt, Au, Cu, Mg, Al, Ba, In, Ag, Au, Ca, Sm, W or Li, or any combination or alloy of those metals.

In various embodiments, the first coil 100 may include a plurality of loops. Each loop of the plurality of loops of the first coil 100 may extend from the first metallization layer 1020 to the fourth metallization layer 1100.

Each loop may include one region 102 of the first metallization layer, two vias 120, and one region 110 of the fourth metallization layer. Each loop of the first coil 100, except for a first and a last loop, may be electrically coupled to two adjacent loops of the first coil 100. Electrical coupling of the individual loops of the first coil may be achieved by means of the regions 102 of the first metallization layer 1020, the vias 120, and the regions 110 of the fourth metallization layer 1100, for example by means of electrical connections between the regions 102 of the first metallization layer 1020, the vias 120, and the regions 110 of the fourth metallization layer 1100. In various embodiments, the regions 102, 110 and the vias 120 may be electrically coupled such that the first coil 100 is formed in a continuous three-dimensional way.

In a figurative example describing a current 130 flowing through the coil 100 of FIG. 1A, the current 130 that enters the first coil 100 from the left side in FIG. 1A through the connector 152 successively flows through the first loop formed by region 102₁, via 120₁ₐ, region 110₁, and via 120_{1b}, then leaves the first loop and enters the second loop at region 102₂, followed by via 120ₐ₂, region 110₂, via 120_{b2}, and so on, until it leaves the nth loop after via 120_{nb} and leaves the first coil 100 through the connector 151.

In various embodiments, the current 130 flowing through the first coil 100 may form a magnetic field 140. In a case where the current 130 is a conventional current 130, and the loops are configured in such a way that the current 130 flows in a clockwise direction if seen from a side where the current 130 enters the coil 100, a magnetic south pole S will form at the end of the coil 100 where the current 130 enters the coil 100.

In various embodiments, a number of loops of the plurality of loops of the first coil 100 may be in a range from 2 to about 1000, for example in a range from about 5 to about 500, for example in a range from about 10 to 50.

FIG. 2 shows a second coil 200 of an inductor in accordance with various embodiments. By way of example, the second coil 200 may be included in an inductor 301 as shown in FIG. 3.

In various embodiments, the inductor may be included in or be part of a semiconductor device or an integrated monolithic circuit.

The second coil 200 may, in its general structure, parts and materials it includes, techniques used for manufacturing it, etc., be similar to the first coil 100.

The second coil 200 may, in various embodiments, include a second metallization layer 2020. The second metallization layer 2020 may be a structured metallization layer. A portion of the second metallization layer 2020 may be structured to form a plurality of regions 202₁, 202₂, 202₃, 202₄, . . . 202ₙ of a second metallization layer 2020. Properties discussed in context with the regions 102 and the first metallization layer 1020 of the first coil 100 may also apply to the regions 202 and to the second metallization layer 2020 of the second coil 200.

The second coil 200 may, in various embodiments, include a third metallization layer 2100. The third metallization layer 2100 may be a structured metallization layer. A portion of the third metallization layer 2100 may be structured to form a plurality of regions 210₁, 210₂, 210₃, 210₄, . . . 210ₙ of a third metallization layer 2100. Properties discussed in context with the regions 110 and the fourth metallization layer 1100 of the first coil 100 may also apply to the regions 210 and to the third metallization layer 2100 of the second coil 200.

The second coil 200 may, in various embodiments, include a plurality of vias 220₁ₐ, 220₂ₐ, 220₃ₐ, . . . 220ₙₐ and 220_{1b}, 220_{2b}, 220_{3b}, . . . 220_{nb}, wherein the vias 220 indexed with “a” may form a first row of vias 220ₐ, and the vias 220 indexed with “b” may form a second row of vias 220_{b}. Properties discussed in context with the vias 120 of the first coil 100 may also apply to vias 220 of the second coil 200.

In various embodiments, the second coil 200 may show a mirror symmetry with respect to the first coil 100. In various embodiments, the mirror symmetry may be such that, if a current 130 for example enters the first coil 100 from the left, as shown in FIG. 1A, and forms a magnetic field 140 with a specific direction (south pole S to the left, north pole N to the right in FIG. 1A), a current 230 entering the second coil 200 from the opposite direction (from the right in FIG. 2) would form a magnetic field 240 which has the same orientation (south pole S to the left, north pole N to the right in FIG. 2) as the magnetic field 140 of the first coil 100.

More generally, in various embodiments, the first coil 100 and the second coil 200 may not be completely mirror symmetric, but only their helicities may be mirror symmetric. For example the first coil 100 may be a right-handed helix, and the second coil 200 may be a left-handed helix, or vice versa, or, to phrase it differently, a current entering both the first coil 100 and the second coil 200 from the same direction would flow clockwise in one coil of the first coil 100 and the second coil 200, and flow counter-clockwise in the other coil of the first coil 100 and the second coil 200.

In various embodiments, the second coil 200 may be smaller than the first coil, for example, a width b of the second coil 200 (also referred to as b₂) and a height h of the second coil 200 (also referred to as h₂) may be smaller than the width b₁ and the height h₁ of the first coil 100. In various embodiments, a length l of the second coil 200 (also referred to as l₂) may be approximately the same as the length l₁ of the first coil 100. In various embodiments, the second coil 200 may be shorter or longer than the first coil 100.

In various embodiments, the second coil 200 may include a plurality of loops. Each loop of the plurality of loops of the second coil 200 may extend from the second metallization layer 2020 to the third metallization layer 2100.

Each loop may include one region 202 of the second metallization layer, two vias 220, and one region 210 of the third metallization layer. Each loop of the second coil 200, except for a first and a last loop, may be electrically coupled to two adjacent loops of the second coil 200. Electrical coupling of the individual loops of the second coil 200 may be achieved by means of the regions 202 of the second metallization layer 2020, the vias 220, and the regions 210 of the third metallization layer 2100, for example by means of electrical connections between the regions 202 of the second metallization layer 2020, the vias 220, and the regions 210 of the third metallization layer 2100. In various embodiments, the regions 202, 210 and the vias 220 may be electrically coupled such that the second coil 200 is formed in a continuous three-dimensional way.

In various embodiments, a number of loops of the plurality of loops of the second coil 200 may be in a range from 2 to about 1000, for example in a range from about 5 to about 500, for example in a range from about 10 to 50.

FIG. 3A shows a schematic perspective view of an inductor 301 for a semiconductor device in accordance with various embodiments, and FIG. 3B shows a schematic cross section of the inductor 301.

In various embodiments, the inductor 301 may include a first coil 100 and a second coil 200. The second coil 200 may be arranged within an inner space 332 defined by the first coil 100. The first coil 100 may for example correspond to the first coil 100 described in context with FIG. 1, and properties discussed in context with the first coil 100, the parts it may include, methods that may be employed for its formation, and the like, may also apply to the first coil 100 of the inductor 301. The second coil 200 may for example correspond to the second coil 200 described in context with FIG. 2; properties discussed in context with the second coil 200, the parts it may include, methods that may be employed for its formation, and the like, may also apply to the second coil 200 of the inductor 301.

In various embodiments, the inductor 301 may include a plurality of structured metallization layers 1020, 2020, 2100, 1100. The plurality of structured metallization layers 1020, 2020, 2100, 1100 may at least include a first metallization layer 1020, a second metallization layer 2020 disposed over the first metallization layer 1020, a third metallization layer 2100 disposed over the second metallization layer 2020, and a fourth metallization layer 1100 disposed over the third metallization layer 2100. In other words, each of the structured metallization layers 1020, 2020, 2100, 1100 may be arranged in a different plane, always one over the other.

In various embodiments, a portion of the first metallization layer 1020 and a portion of the fourth metallization layer 1100 of the plurality of structured metallization layers 1020, 2020, 2100, 1100 may form the first coil. In various embodiments, the portion of the first metallization layer 1020 and the portion of the fourth metallization layer 1100 may be configured, e.g. electrically connected, to form the first coil 100.

In various embodiments, a portion of the second metallization layer 2020 and a portion of the third metallization layer 2100 of the plurality of structured metallization layers 1020, 2020, 2100, 1100 may form the second coil 200. In various embodiments, the portion of the second metallization layer 2020 and the portion of the third metallization layer 2100 may be configured, e.g. electrically connected, to form the second coil 200.

In various embodiments, the second coil 200 may be arranged within an inner space defined by the first coil 100. The inner space defined by the first coil 100 may be the region that is surrounded or enclosed by the loops of the first coil 100. Boundaries of the inner space defined by the first coil 100 may be planes tangentially contacting surfaces of the regions 102, 110 and vias 120 facing towards an inside of the first coil 100, a plane tangentially contacting surfaces of the regions 102₁, 110₁, 120₁ₐ and 120_{1b} facing towards an end of the first coil 100 closest to them, and a plane tangentially contacting surfaces of the regions 102ₙ, 110ₙ, 120ₙₐ and 120_{nb} facing towards an end of the first coil 100 closest to them.

In various embodiments, the second coil 200 may be arranged completely within the inner space defined by the first coil 100. In other words, the second coil 200 may be arranged within the inner space defined by the first coil 100 such that no parts of the second coil 200, with a possible exception of one or more electrical connectors 251, 252, protrude beyond outer boundaries of the first coil 100. Phrased yet differently, the second coil 200 may be arranged within the inner space defined by the first coil 100 such that at least all loops that are included in the second coil 200 are arranged within the inner space defined by the first coil 100. In that case, a size of the inductor 301 may be the same as a size of the first coil 100. A height hᵢ, width bᵢ and length lᵢ of the inductor may be defined analogously to the heights, widths and lengths of the coils 100, 200 as described in context with FIG. 1 and FIG. 2. In various embodiments, values of the height hᵢ, width bᵢ and length lᵢ of the inductor may correspond to those specified in context with the coil 100.

In various embodiments, as for example shown in FIG. 3A, the second coil may be arranged within the inner space defined by the first coil 100 such that it extends beyond the inner space defined by the first coil 100. In other words, the first coil 100 may be arranged only partly within the inner space defined by the first coil 100. In other words, the second coil 200 may be arranged within the inner space defined by the first coil 100 such that it appears shifted along its long axis 268 out of the inner space defined by the first coil 100. In other words, the second coil 200 may be arranged within the inner space defined by the first coil 100 such that some of its loops protrude from the inner space defined by the first coil 100. In that case, the size of the inductor 301 may be different from the size of the first coil 100. In various embodiments, the values of the height hᵢ and of the width bᵢ of the inductor 301 may correspond to those specified in context with the coil 100, but the length lᵢ may be larger than that of the first coil l₁. In various embodiments, the length lᵢ of the inductor 301 may be larger than the length l₁ of the first coil 100 and smaller than the sum of the length l₁ of the first coil 100 and the length l₂ of the second coil 200. The length lᵢ of the inductor 301 may for example be in a range from about l₁ to about l₁+0.9×l₂.

In various embodiments, the first coil 100 and the second coil 200 may be arranged with their long axes 168 and 268, respectively, in parallel. In various embodiments, the first coil 100 and the second coil 200 may be arranged such that the long axis 168 of the first coil 100 and the long axis 268 of the second coil 200 coincide.

In various embodiments, a number of loops of the inductor 301 may correspond to a sum of a number of loops of the first coil 100 and of the number of loops of the second coil 200. Thus, the number of loops of the inductor 301 may be in a range from about 4 to about 2000, for example from about 10 to about 1000, for example from about 20 to about 100.

In various embodiments, the first coil 100 may include at least one electrical connector 151, 251. In various embodiments, the second coil 200 may include at least one electrical connector 151, 251. One or more of the electrical connectors 151, 251 may serve for electrically coupling, for example for electrically connecting, the first coil 100 and the second coil 200. Alternatively or additionally, one or more of the electrical connectors 151, 251 may serve for electrically coupling, for example for electrically connecting, the inductor 301, for example for electrically connecting the inductor 301 to an integrated circuit, to a power source, to other parts or electrically conductive structures of the semiconductor device.

In various embodiments, the first coil 100 and the second coil 200 of the inductor 301 may be electrically coupled in series, such that a current 330 entering one of the first coil 100 and the second coil 200 will flow through the coil, will then flow through the electrical coupling of the first coil 100 and the second coil 200, and will then flow through the other one of the first coil 100 and the second coil 200. In the example shown in FIG. 3A, the current 330 entering the inductor 301 by means of the electrical connector 251 of the second coil 200 may flow through the second coil 200 (in a counter-clockwise direction), may then flow through an electrical connection between the second coil 200 and the first coil 100 (not shown here, but see FIG. 5), may then flow through the first coil 100 (in a clockwise direction), and may then leave the inductor 301 by means of the electrical connector 151 of the first coil 100.

The schematic cross section of the inductor 301 shown in FIG. 3B as seen from the left in FIG. 3A shows schematically the direction of the current 330 in the inductor 301. The parts 102, 120ₐ, 120_{b} and 110 of the first inductor 100, and also the current 330 flowing through them, that appear to be forming closed ring-like structures, are to be understood as appearing as a ring only because of appearing projected that way, and to represent a three-dimensional helical structure as seen in FIG. 3A. Similarly, the parts 202, 220ₐ, 220_{b} and 210 of the second inductor 200, and also the current 330 flowing through them, that appear to be forming closed ring-like structures, are to be understood as appearing as a ring only because of appearing projected that way, and to represent a three-dimensional helical structure as seen in FIG. 3A.

In various embodiments, the current 330 may flow in parallel in adjacent parts of the first coil 100 and of the second coil 200. The current 330 may flow through the region 102 of the first coil 100 in the same direction as through the adjacent region 202 of the second coil 200 (the region 102 and the adjacent region 202 may together be referred to as “a bottom group of adjacent regions”), the current 330 may flow through the via 120ₐ of the first coil 100 in the same direction as through the adjacent via 220ₐ of the second coil 200 (the via 120ₐ and the adjacent via 220ₐ may together be referred to as “a left group of adjacent vias”), the current 330 may flow through the region 110 of the first coil 100 in the same direction as through the adjacent region 210 of the second coil 200 (the region 110 and the adjacent region 210 may together be referred to as “a top group of adjacent regions”), and the current 330 may flow through the via 120_{b} of the first coil 100 in the same direction as through the adjacent via 220_{b} of the second coil 200 (the via 120_{b} and the adjacent via 220_{b} may together be referred to as “a right group of adjacent vias”). In other words, the current 330 may flow through the first coil 100 and the second coil 200 in such a way that the direction of the current 330 in each loop of the first coil 100 is parallel to the direction of the current 330 in each loop of the second coil 200.

The above configuration of the inductor 301 may cause the magnetic fields 140 and 240 (see FIG. 1A and FIG. 2, respectively) formed by the first coil 100 and the second coil 200, respectively, to have the same orientation. In other words, the north pole N of the magnetic field 140 formed by the first coil 100 is pointing towards the same direction as the north pole N of the magnetic field 240 formed by the second coil 200.

In various embodiments, the direction of the current 330 need not be the direction indicated in FIG. 3B. In both coils 100, 200 together, the current 330 could be flowing in an opposite direction.

In various embodiments, as shown in FIG. 3B, the first coil 100 of the inductor 301 may define an active area A1 of the first coil 100. The active area A1 of the first coil 100 may be an area of the inner space defined by the first coil 100, measured in a plane orthogonal to the long axis 168 of the first coil 100.

In various embodiments, as shown in FIG. 3B, the second coil 200 of the inductor 301 may define an active area A2 of the second coil 200. The active area A2 of the second coil 200 may be an area of an inner space 432 defined by the second coil 200, measured in a plane orthogonal to the long axis 268 of the second coil 200.

In various embodiments, an inductively L of the inductor 301 may be given by L=N²×μ₀A/l, wherein N is the number of loops, μ₀ is the magnetic constant, A is the active area and l is the length of the inductor 301. The inductively of the inductor 301, in comparison with an inductor that would consist of only one coil, like for example the coil 100, would almost be four times as high, because the number of loops N would have doubled, and the area A2 of the second coil 200 would only be slightly smaller than the area A1 of the first coil 100.

In various embodiments, the active area A2 of the second coil 200 may be as large as possible with respect to the constraints set by the first coil 100. In other words, the regions 202 of the structured second metallization layer 2020, the vias 220a and 220b and the regions 210 of the structured third metallization layer 2100 may each be as close as possible, without compromising the intended use of the inductor 301 (e.g., without increasing the risk of creating short-circuits), to their respective adjacent parts of the first coil 100, i.e. to the regions 102 of the structured first metallization layer 1020, the vias 120a and 120b, and to the regions 110 of the structured fourth metallization layer 1100.

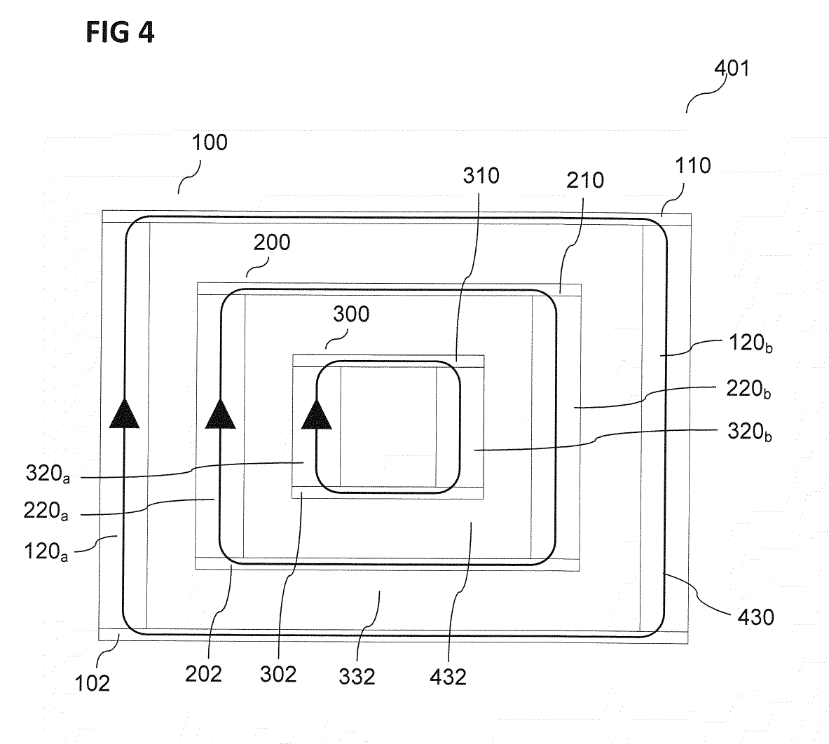

As shown in FIG. 4, which shows a schematic cross section of an inductor 401 in accordance with various embodiments, an inductor 401 may include more than two coils 100, 200. The inductor 401 may be considered as being formed by an inductor with two coils, for example by an inductor like the inductor 301 described in context with FIG. 3A, FIG. 3B and FIG. 5, with a further addition of at least a third coil 300 and connectors for an electrical coupling of the at least third coil 300 to at least one of the first coil 100 and the second coil 200, and/or for forming an electrical connector (an outside connector) of the inductor 401. Detailed descriptions of the exemplary inductor 401 will therefore be limited to those parts of the inductor 401 that were added with respect to the inductor 301.

The inductor 401 may include any number of coils, wherein each additional coil 300, . . . may be arranged within the inner space of the thereto innermost coil, and wherein the coils are configured such that magnetic fields formed by each of the coils are oriented in the same way. In other words, a current flowing through all the coils 100, 200, 300, . . . may flow in the same direction through adjacent parts of the individual coils, e.g. through regions 102, 202, 302, . . . The example of the inductor 401 with three coils 100, 200, 300 will be described below in more detail, but general concepts, features etc. described there and in other parts of the description may apply, if applicable, also to an inductor with more than three coils, and general concepts, features etc. described in context with the inductor 301 may also apply, if applicable, to the inductor 401 with its three coils or to an inductor with more than three coils.

In various embodiments, the inductor 401 may be included in or be part of a semiconductor device.

The third coil 300 may, in its general structure, parts and materials it includes, techniques used for manufacturing it, etc., be similar to the first coil 100 and/or to the second coil 200.

The third coil 300 may, in various embodiments, include a fifth metallization layer disposed over the second metallization layer 2020. The fifth metallization layer may be a structured metallization layer. A portion of the fifth metallization layer may be structured to form a plurality of regions 302 of the structured fifth metallization layer. Properties discussed in context with the regions 102 and the structured first metallization layer 1020 of the first coil 100 and/or with the regions 202 and the structured second metallization layer 2020 of the second coil 200 may also apply to the regions 302 and to the structured fifth metallization layer of the third coil 300.

The third coil 300 may, in various embodiments, include a sixth metallization layer disposed over the fifth metallization layer. The sixth metallization layer 3100 may be a structured metallization layer. A portion of the sixth metallization layer may be structured to form a plurality of regions 310 of the structured sixth metallization layer. Properties, methods etc. discussed in context with the regions 110 and the structured second metallization layer 1100 of the first coil 100 and/or with the regions 210 and the structured fourth metallization layer 2100 of the second coil 200 may also apply to the regions 310 and to the structured sixth metallization layer of the third coil 300.

The third coil 300 may, in various embodiments, include a plurality of vias 320ₐ and 320_{b}, wherein the vias 320 indexed with “a” may form a first row of vias 320ₐ, and the vias 320 indexed with “b” may form a second row of vias 320_{b}. Properties, methods etc. discussed in context with the vias 120 of the first coil 100 and/or with the vias 220 of the second coil 200 may also apply to vias 320 of the third coil 300.

In various embodiments, the third coil 300 may have the same general configuration as the first coil 100 (and/or as the second coil 200). A helicity of the third coil 300 may be the same as the helicity of the first coil 100 (and/or of the second coil 200), i.e. both the first coil 100 and the third coil 300 may be right-handed helices, or both the first coil 100 (second coil 200) and the third coil 300 may be left-handed helices, or, to phrase it differently, a current 430 entering both the first coil 100 (second coil 200) and the third coil 300 from the same direction would flow either clockwise in both coils of the first coil 100 (second coil 200) and the third coil 300, or flow counter-clockwise both coils of the first coil 100 (second coil 200) and the third coil 300.

In various embodiments, the helicity of the third coil 300 may be different from the helicity of the first coil 100 (and/or of the second coil 200), i.e. the first coil 100 (and/or the second coil 200) may be a right-handed helix, and the third coil 300 may be a left-handed helix, or vice versa, or, to phrase it differently, the current 430 entering both the first coil 100 (and/or of the second coil 200) and the third coil 300 from the same direction would flow clockwise in one coil of the first coil 100 (second coil 200) and the third coil 300, and flow counter-clockwise in the other coil of the first coil 100 (second coil 200) and the third coil 300.

In various embodiments, the third coil 300 may be smaller than the second coil 200, for example, a width b of the third coil 300 (also referred to as b₃) and a height h of the third coil 300 (also referred to as h₃) may be smaller than the width b₂ and the height h₂ of the second coil 200. In various embodiments, a length l of the third coil 300 (also referred to as l₃) may be approximately the same as the length l₂ of the second coil 200. In various embodiments, the third coil 300 may be shorter or longer than the second coil 200. In various embodiments, the third coil 300 may be shorter or longer than the first coil 100. In various embodiments, the third coil 300 may have the same length as the first coil 100.

In various embodiments, the third coil 300 may include a plurality of loops. Each loop of the plurality of loops of the third coil 300 may extend from the structured fifth metallization layer 3020 to the structured sixth metallization layer 3100.

Each loop may include one region 302 of the fifth metallization layer 3020, two vias 320, and one region 310 of the sixth metallization layer 3100. Each loop of the third coil 300, except for a first and a last loop, may be electrically coupled to two adjacent loops of the third coil 300. Electrical coupling of the individual loops of the third coil 300 may be achieved by means of the regions 302 of the fifth metallization layer 3020, the vias 320, and the regions 310 of the sixth metallization layer 3100, for example by means of electrical connections between the regions 302 of the structured fifth metallization layer 3020, the vias 320, and the regions 310 of the structured sixth metallization layer 3100. In various embodiments, the regions 302, 310 and the vias 320 may be electrically coupled such that the third coil 300 is formed in a continuous three-dimensional way.

In various embodiments, a number of loops of the plurality of loops of the third coil 300 may be in a range from 2 to about 1000, for example in a range from about 5 to about 500, for example in a range from about 10 to 50.

In various embodiments, the inductor 401 may be configured in such a way that a current 430 can flow sequentially through all three coils 100, 200, 300. For example, the coils 100, 200 and 300 may be electrically coupled in series. An electrical coupling, for example an electric connection, between the first coil 100, the second coil 200, and the third coil 300, may for example be achieved by means of the regions 102, 202, 302, 110, 210 and/or 310, the vias 120, 220 and/or 320, and/or by means of dedicated electrical connectors.

Further electrical connectors may be used for connecting the inductor 401, for example for connecting the inductor 401 to a power source, an integrated circuit, another element of the semiconductor device, etc. The further electrical connectors (also referred to as “external connectors”) may be electrically coupled, for example electrically connected, to two coils of the first coil 100, the second coil 200 and the third coil 300.

In various embodiments, the helicity of each of the coils 100, 200, and 300 may determine which end of each coil 100, 200 and 300 may be electrically connected to one of the ends of the other coils or to one of the further electrical connectors, in order to obtain a serial connection of the three coils 100, 200 and 300 in which the coils 100, 200 and 300 are arranged and electrically connected in such a way that the magnetic fields 140, 240 and 340 formed by the first coil 100, the second coil 200 and the third coil 300, respectively, are oriented in the same way.

This may be achieved by arranging and electrically coupling the plurality of coils 100, 200 and 300 in such a way that in all those parts of the three coils that are adjacent to each other, e.g., in the vias 120ₐ, 220ₐ, and 320ₐ (the left group of adjacent vias), in the regions 102, 202, and 302 (the bottom group of adjacent regions), in the regions 110, 210 and 310, (the top group of adjacent regions) and in the vias 120_{b}, 220_{b}, and 320_{b} (the right group of adjacent vias), the current 430 flows in the same direction. For example, in FIG. 4 the current 430 flows upwards in the left group of adjacent vias, it flows to the right in the top group of adjacent vias, downwards in the right group of adjacent vias, and to the left in the bottom group of adjacent regions.

FIG. 5 shows a schematic view of one end of an inductor 301 in accordance with various embodiments. The end of the inductor 301 shown in FIG. 5 may for example represent the left side end of the inductor 301 of FIG. 3A.

FIG. 5 shows the electrical coupling of the first coil 100 and of the second coil 200 according to various embodiments. The electrical coupling, for example by means of an electric connection, may for example be achieved by electrically coupling the nth via 220_{nb} of the second coil 200 to the first region 102₁ of the structured first metallization layer 1020 by means of an additional via 550, wherein the additional via 550 electrically contacts both, the via 220_{nb} and the region 102₁.

The electrical coupling of the first coil 100 and the second coil 200 could, in various embodiments, have been established using other structures of the first coil 100 and/or of the second coil 200, and other additional contact structures, for example by electrically connecting the region 210ₙ of the third metallization layer 2100 of the second coil 200 with the (shortened) via 120_{1b} by means of an additional electrically conductive structure connecting the region 210ₙ of the second coil 200 with the (shortened) via 120_{1b} (not shown). In that case, the additional electrically conductive structure could be formed from a structure of the structured third metallization layer 2100.

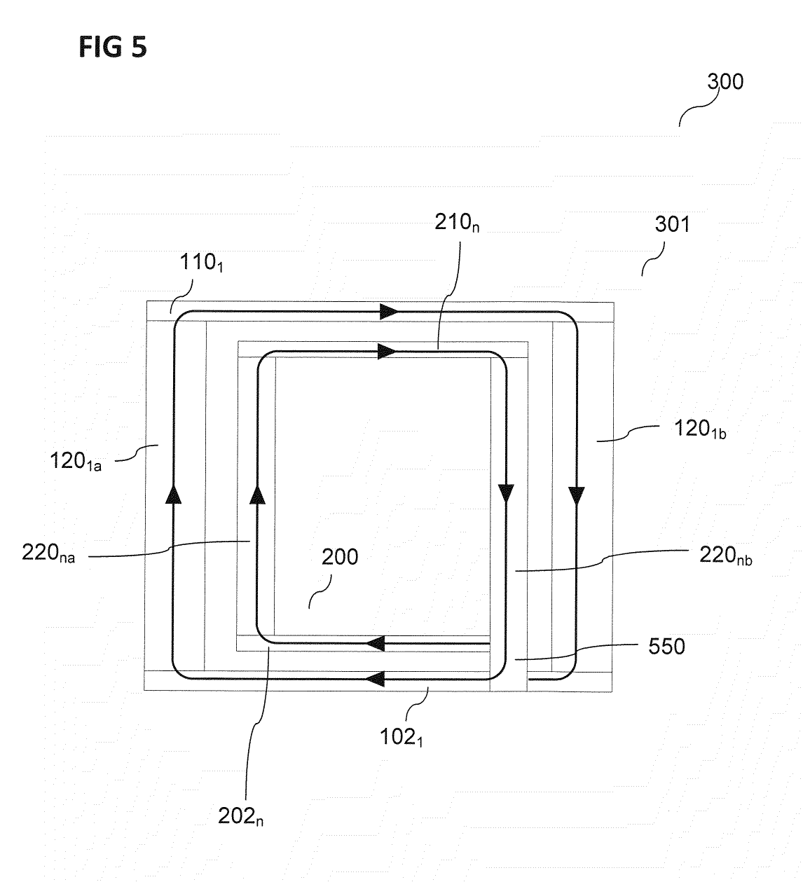

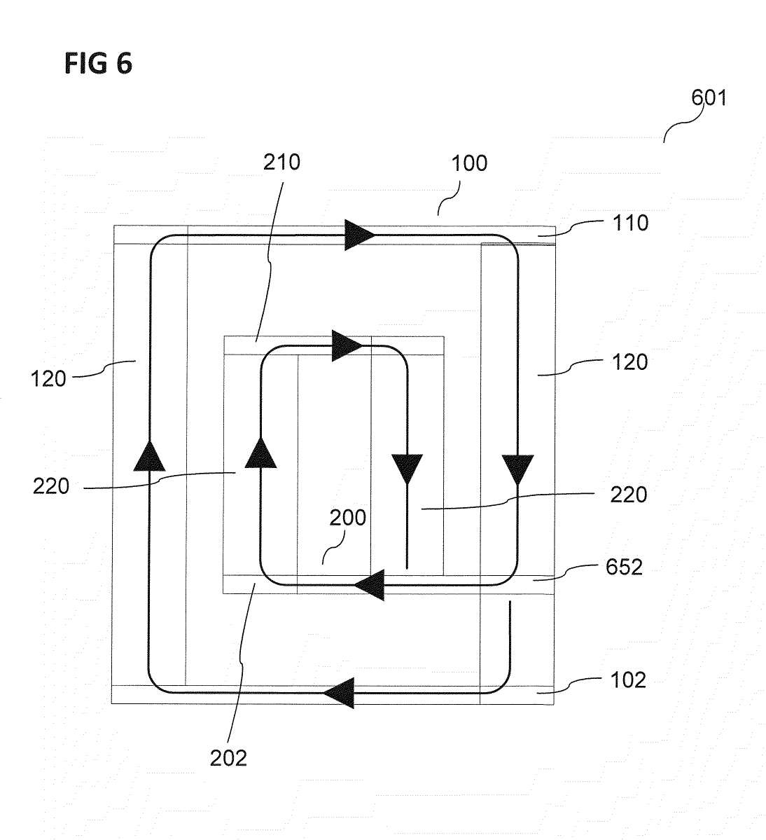

A structure for connecting the first coil 100 and the second coil 200 similar to the one just described is shown in FIG. 6. FIG. 6 shows a schematic view of one end of an inductor 601 in accordance with various embodiments. Here, the region 202 of the second metallization layer 2020 of the second coil 200 is electrically coupled to the (shortened) via 120 of the first coil 100 by means of an electrically conductive structure 652. In various embodiments, the electrically conductive structure 652 may be a structure of the structured third metallization layer 2020.

In various embodiments, if the first coil 100 and the second coil 200 have different helicities, i.e. if one is a left-handed helix and the other is a right-handed helix, the first coil 100 and the second coil 200 may be electrically connected at the same end, as for example shown in FIG. 5 and in FIG. 6.

In various embodiments, if the first coil 100 and the second coil 200 have the same helicity, i.e. if they are both either left-handed helices or both right-handed helices, the electrical connection of the first coil 100 and the second coil 200 may need to be established between one end of one coil and the opposite end of the other coil. This applies in a similar fashion also to inductors with more than two coils.

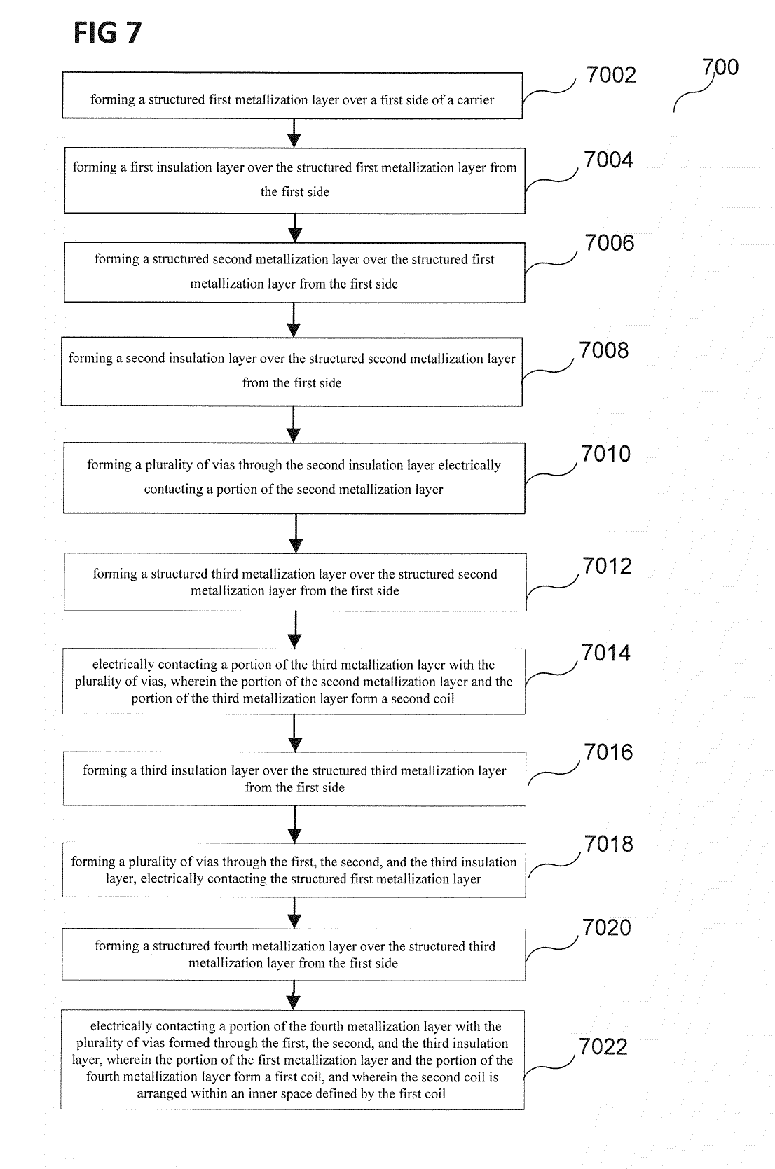

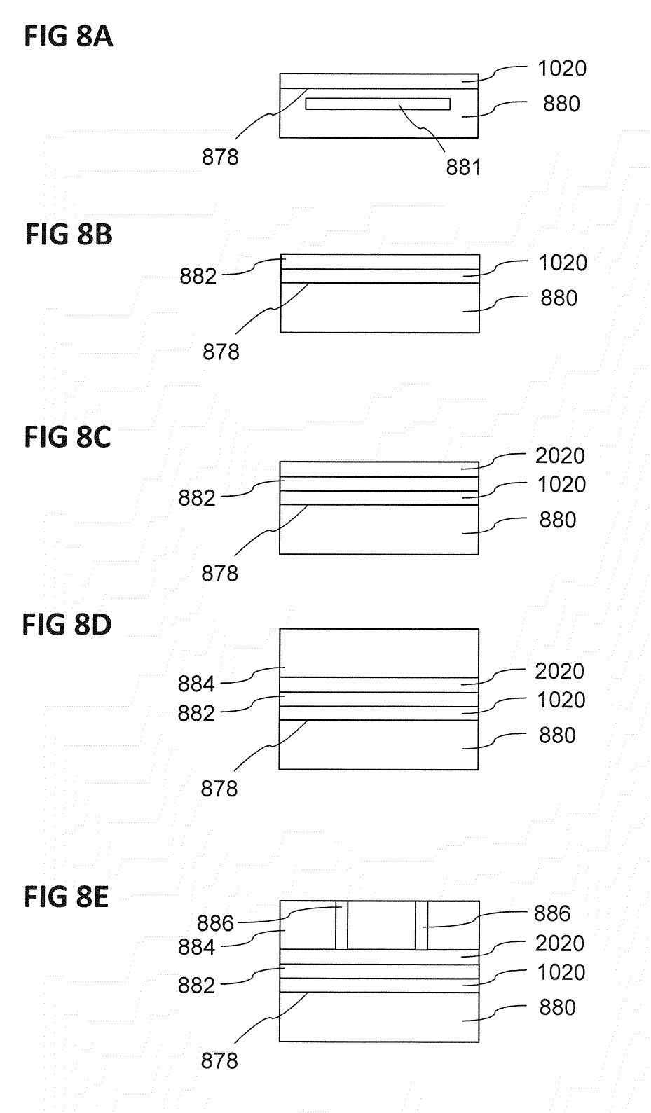

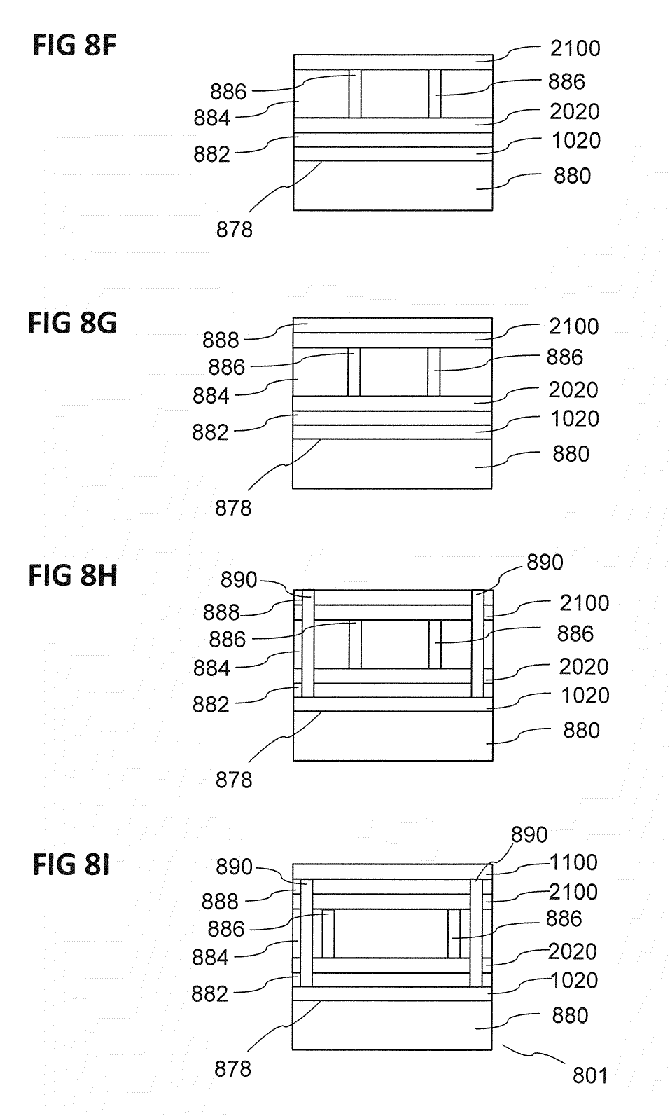

FIG. 7 shows a schematic diagram 700 of a method of forming an inductor for a semiconductor device, and FIG. 8A to FIG. 8I show a process flow for a method of forming an inductor 801 for a semiconductor device.

Methods, materials, shapes, parameters, techniques, concepts etc. described in context with the method of forming an inductor for a semiconductor device may also apply to the inductor, and vice versa.

The method of forming an inductor 801 for a semiconductor device, as shown in FIG. 7 and FIG. 8A to FIG. 8I, and in accordance with various embodiments, may include, in 7002, forming a structured first metallization layer 1020 over a first side 878 of a carrier 880 (FIG. 8A); forming, in 7004; a first insulation layer 882 over the structured first metallization layer 1020 from the first side 878 (FIG. 8B); forming, in 7006, a structured second metallization layer 2020 over the structured first metallization layer 1020 from the first side 878 (FIG. 8C); forming, in 7008, a second insulation layer 884 over the structured second metallization layer 2020 from the first side 878 (FIG. 8D); forming, in 7010, a plurality of vias 886 through the second insulation layer 884 electrically contacting a portion of the second metallization layer 2020 (FIG. 8E); forming, in 7012, a structured third metallization layer 2100 over the structured second metallization layer 2020 from the first side 878, electrically contacting, in 7014, a portion of the third metallization layer 2100 with the plurality of vias 886, wherein the portion of the second metallization layer 2020 and the portion of the third metallization layer 2100 form a second coil (FIG. 8F); forming, in 7016, a third insulation layer 888 over the structured third metallization layer 2100 from the first side 878 (FIG. 8G); forming, in 7018, a plurality of vias 890 through the first 882, the second 884, and the third 888 insulation layer, electrically contacting the structured first metallization layer 1020 (FIG. 8H); forming, in 7020, a structured fourth metallization layer 1100 over the structured third metallization layer 2100 from the first side 878; and electrically contacting, in 7022, a portion of the fourth metallization layer 1100 with the plurality of vias 890 formed through the first 882, the second 884, and the third 888 insulation layer, wherein the portion of the first metallization layer 1020 and the portion of the fourth metallization layer 1100 form a first coil, and wherein the second coil is arranged within an inner space defined by the first coil (FIG. 8I).

The structured first 1020, second 2020, third 2100 and fourth 1100 metallization layers may for example be or include metallization layers formed during a back-end-of-line-process in an integrated circuit for electrically contacting one or more semiconductor devices 881 of the integrated circuit.

Forming the structured first 1020, second 2020, third 2100 or fourth 1100 metallization layers may, in various embodiments, include directly forming the structured metallization layer. In various embodiments it may include first forming the metallization layer, and then structuring it, for example by means of photolithography.

The structured metallization layers 1020, 2020, 2100, 1100 may be formed by means of any suitable method, for example by means of methods typically used for forming (structured) metallization layers in semiconductor devices. Methods for forming the metallization layers 1020, 2020, 2100, 1100 may for example include deposition, for example by means of chemical vapor deposition (CVD), physical vapor deposition (PVD), or electrochemical deposition.

In various embodiments, the structured metallization layers 1020, 2020, 2100, 1100 may include any conductive material, for example any conductive material that is used for forming metallization layers in semiconductor devices. The metallization layers 1020, 2020, 2100, 1100 may for example include Ag, Pt, Au, Cu, Mg, Al, Ba, In, Ag, Au, Ca, Sm or Li, or any combination or alloy of those metals.

The first 882, second 884 and third 888 insulation layers may for example be or include interlayer dielectrics formed during a back-end-of-line-process in an integrated circuit between the metallization layers used for electrically contacting the semiconductor devices 881 formed in the integrated circuit. In various embodiments, the semiconductor devices 881 may include electronic components such as e.g. diodes, capacitors, resistors, transistors (e.g. field effect transistors and/or bipolar transistors), and the like.

Forming the first 882, second 884 and third 888 insulation layers may, in various embodiments, include forming an electrically insulating layer 882, 884, 888. In various embodiments, the insulation layer 882, 884, and/or 888 may be dielectric, for example by means of a dielectric (electrically insulating) material, for example silicon dioxide, silicon nitride, silicon oxynitride or the like, and the insulation layer 882, 884, and/or 888 may for example be applied by means of deposition, for example by means of chemical vapor deposition. Alternatively, the insulation layer 882, 884, and/or 888 could be partially dielectric. For example, the insulation layer 882, 884, and/or 888 may have a layered setup, in which conductive and/or semiconductive layers are arranged between dielectric layers, wherein the dielectric layers prevent an electric contact, or a semiconductive or conductive material included in the insulation layer 882, 884, and/or 888 could have an electrically insulating film formed at least in those regions where the insulation layer 882, 884, and/or 888 would otherwise come into contact with conductive parts (e.g., in case of the insulation layer 882, the conductive parts could be the first metallization layer 1020, the second metallization layer 2020, and/or the individual regions 102₁, 102₂, . . . 102ₙ of the first metallization layer 1020) that it is supposed to electrically insulate, or the like.

In various embodiments, the first 882, second 884 and third 888 insulation layer may have a thickness in a range from about 20 nm to about 5 μm, for example from about 50 nm to about 2 μm.

In various embodiments, the second insulation layer 884 may have a larger thickness than the first insulation layer 882 and the third insulation layer 888. For example, the thickness of the second insulation layer 884 may be in a range from about 500 nm to about 2 μm, and the thicknesses of the first insulation layer 882 and of the third insulation layer 888 may be in a range from about 20 nm to about 200 nm. In this way, an active area of the first coil A1 and an active area of the second coil A2 (see description in context with e.g. FIG. 3B) may be large. In various embodiments, thicknesses of the first 882, second 884 and third 888 insulation layer may be similar.

The insulation layer 882 may electrically insulate the first metallization layer 1020 from the second metallization layer 2020, except where an electrical contact is desired or required, for example if a contact between the first coil and the second coil is established by means of electrically coupling a region of the first metallization layer 1020 to a region of the second metallization layer 2020.

In various embodiments, the first insulation layer 882 may electrically insulate the individual regions 102₁, 102₂, . . . 102ₙ of the first metallization layer 1020 (see for example FIG. 1 or FIG. 3A) from each other. A material or materials used for forming the first insulation layer 882 may extend to areas in between the regions 102 in the plane of the first metallization layer 1020. Alternatively, a dedicated insulation structure may be formed in the areas between the regions 102, and then the insulation layer 882 may be formed on the structured first metallization layer 1020 and on the insulation structure.

The second 884 and third 888 insulation layers may in various embodiments be similar to the first insulation layer 882, for example regarding a function of the insulation layers of electrically insulating adjacent conductive layers, structures, regions and/or parts from each other, or regarding the methods and materials used for forming the insulation layers 884, 888.

In various embodiments, forming the pluralities of vias 886, 890 may be performed using any suitable method for forming vias through the insulation layers 882, 884 and/or 888, and/or through the metallization layers 2020 and/or 2100. Methods for forming the vias 886, 890 may for example include forming openings in the insulation layers 882, 884 and/or 888, and/or through the metallization layers 2020 and/or 2100, for example by means of photolithography or laser drilling, and filling the openings with electrically conductive material, for example a metal or a metal alloy, for example a material as described in context with the structured metallization layers. The vias 886, 890 may, at their respective ends or end surfaces, be electrically coupled, for example electrically connected, to portions of the structured metallization layers 1020, 2020, 2100 and/or 1100, respectively. Each of the vias 890 may for example be electrically coupled to one region 102 of the first structured metallization layer 1020 and to one region 110 of the fourth structured metallization layer 1100 (for the regions 102 and 110 and for an exception applying to the first and last via, see for example FIG. 1 or FIG. 3A and the respective description). Each of the vias 886 may for example be electrically coupled to one region 202 of the second structured metallization layer 2020 and to one region 210 of the third structured metallization layer 2100 (for the regions 202 and 210 and for an exception applying to the first and last via, see for example FIG. 2 or FIG. 3A and the respective description).

The vias 890 formed through the first 882, second 884 and third 888 insulation layer may, in general, not be electrically connected to the second metallization layer 2020 or to the third metallization layer 2100, except if they are used for establishing an electric connection between the first coil and the second coil. The vias 890 may, in various embodiments, penetrate a plane of the second metallization layer 2020 and a plane of the third metallization layer 2100 in an area of the respective planes where no regions 202 of the second metallization layer 2020 and no regions 210 of the third metallization layer 2100 (see e.g. FIG. 3A) are formed. Alternatively, an electrical contact between peripheral surfaces of the vias 890 and the second 2020 and/or third 2100 metallization layer may be prevented, for example by means of an electrically insulating layer (not shown) formed on a peripheral surface of the opening. In various embodiments, the vias 890 may be formed after a formation of the fourth metallization layer 1100. In various embodiments, the vias 886 may be formed after the formation of the third metallization layer 2100.

In various embodiments, more coils may be formed by applying the method of forming an inductor for a semiconductor device. For each additional coil, two additional structured metallization layers and two interleaved additional insulation layers and another plurality of vias may be added after half the total number of metallization layers has been formed. In this way, each new coil may be formed within an inner space defined by a thereto innermost coil. As an example, in a case of an insulator with three coils, an insulator as shown in FIG. 4 results. The additional metallization layers and insulation layers for the third coil may be formed after the formation of the second metallization layer 2020, and before the formation of the second insulation layer 884. The third coil may thus be formed within the inner space 432 defined by the second coil.

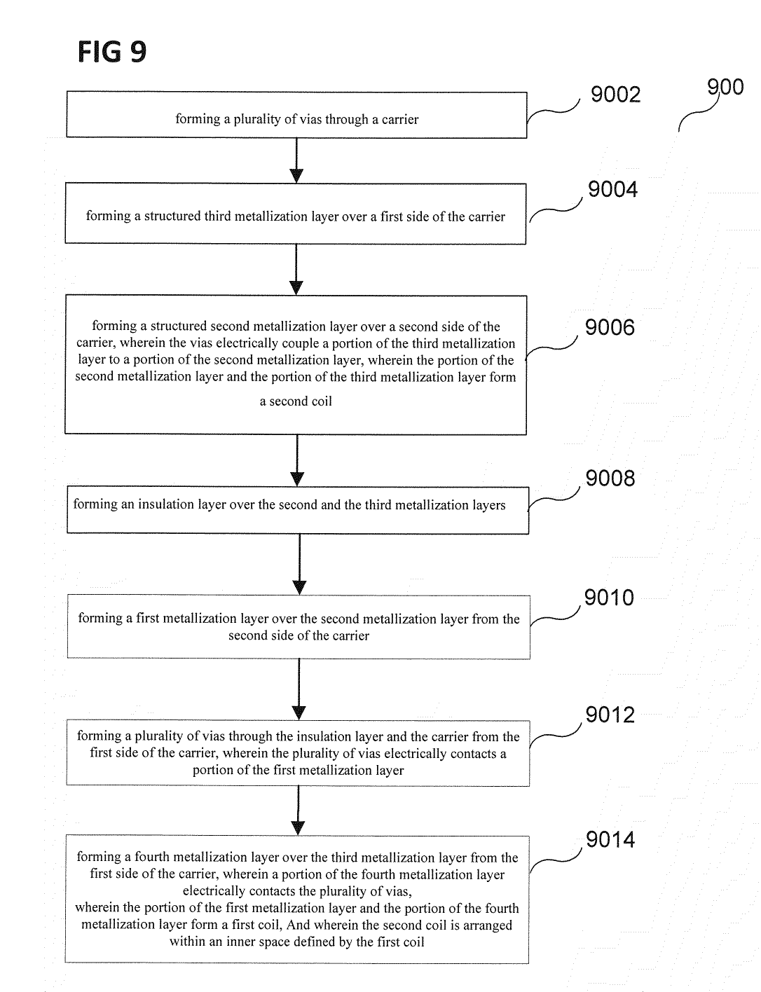

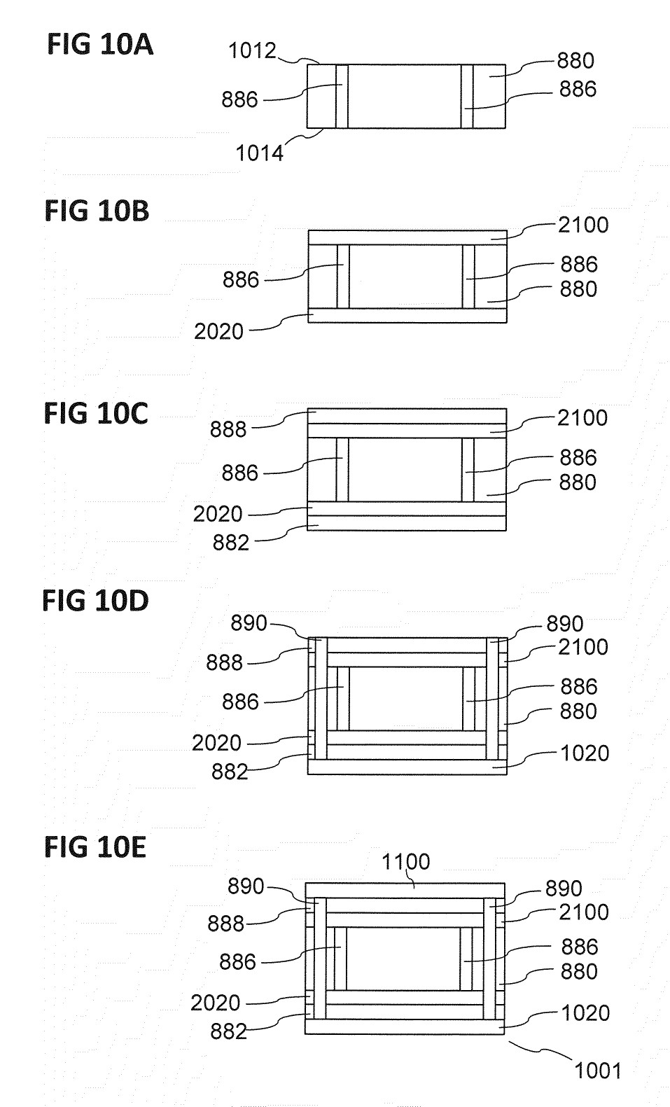

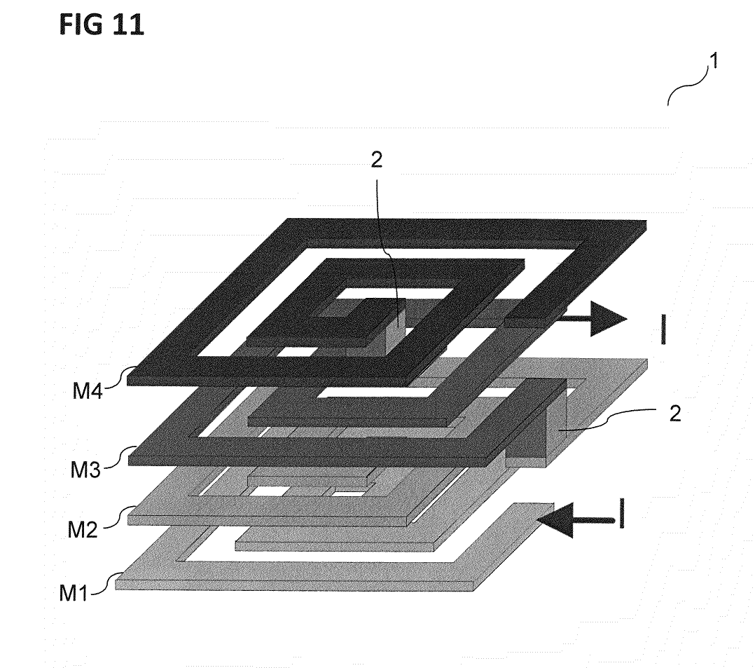

FIG. 9 shows a schematic diagram 900 of a method of forming an inductor for a semiconductor device, and FIG. 10A to FIG. 10E show a process flow for a method of forming an inductor 1001 for a semiconductor device.

Methods, materials, shapes, parameters, techniques, concepts etc. described in context with the method of forming an inductor for a semiconductor device may also apply to the inductor, and vice versa.

The method of forming an inductor 1001 for a semiconductor device, as shown in FIG. 9 and FIG. 10A to FIG. 10E, and in accordance with various embodiments, may include, in 9002, forming a plurality of vias 886 through a carrier 880 (FIG. 10A); forming, in 9004, a structured third metallization layer 2100 over a first side 1012 of the carrier (FIG. 10B); forming, in 9006, a structured second metallization layer 2020 over a second side 1014 of the carrier 880, wherein the vias 886 electrically couple a portion of the third metallization layer 2100 to a portion of the second metallization layer 2020, wherein the portion of the second metallization layer 2020 and the portion of the third metallization layer 2100 form a second coil (FIG. 10B); forming, in 9008, an insulation layer 882, 888 over the second 2020 and the third 2100 metallization layers, respectively (FIG. 10C); forming, in 9010; a first metallization layer 1020 over the second metallization layer 2020 from the second side 1014 of the carrier 880 (FIG. 10D); forming, in 9012, a plurality of vias 890 through the insulation layer 88, 888 and the carrier 880 from the first side 1012 of the carrier 880, wherein the plurality of vias 890 electrically contacts a portion of the first metallization layer 1020 (FIG. 10D); and forming, in 9014, a fourth metallization layer 1100 over the third metallization layer 2100 from the first side 1012 of the carrier 880, wherein a portion of the fourth metallization layer 1100 electrically contacts the plurality of vias 890, wherein the portion of the first metallization layer 1020 and the portion of the fourth metallization layer 1100 form a first coil, and wherein the second coil is arranged within an inner space defined by the first coil (FIG. 10E).

In various embodiments, the formation of the vias 886 may also be performed after the formation of the structured second metallization layer 2020 and/or after the formation of the structured third metallization layer 2100.

In various embodiments, the formation of the vias 890 may also be performed before the formation of the structured first metallization layer 1020 and/or after the formation of the structured fourth metallization layer 1100.

In various embodiments, the fourth metallization layer 1100 may be formed and/or structured at the same time as the first metallization layer 1020.

In various embodiments, the third metallization layer 2100 may be formed and/or structured at the same time as the second metallization layer 2020.

In various embodiments, the method of forming an inductor may be employed for forming an inductor with more than two coils. In that case, additional metallization layers may be added above the first metallization layer 1020 from the second side 1014 of the carrier 880, and above the fourth metallization layer 1100 from the second side 1012 of the carrier 880. A plurality of vias may be formed through the metallization layers, insulation layers and the carrier 880 for forming an electrical coupling between the additional metallization layers.

The carrier 880 may be any carrier suitable for an inductor for a semiconductor device. The carrier 880 may for example be a semiconductor, for example silicon, for example a silicon wafer. The carrier 880 may have a thickness in a range from about 20 μm to about 2 mm, for example from about 50 μm to about 300 μm. In a case of a conductive or semiconductive carrier 880, the vias 886, 890 may be electrically insulated from the carrier 880, for example by means of an electrically insulating layer. In the carrier 880, one or more semiconductor devices 881 may be arranged.

In various embodiments, methods, materials, shapes, parameters, techniques, concepts etc. described in context with the other method of forming the inductor for a semiconductor device, and/or with the inductor as described above, may also apply to the presently described method of forming an inductor, and vice versa.

In various embodiments, an inductor for a semiconductor device is provided. The inductor may include: a plurality of structured metallization layers, wherein the plurality of structured metallization layers may include at least a first metallization layer, a second metallization layer disposed over the first metallization layer, a third metallization layer disposed over the second metallization layer, and a fourth metallization layer disposed over the third metallization layer, wherein a portion of the first metallization layer and a portion of the fourth metallization layer form a first coil, wherein a portion of the second metallization layer and a portion of the third metallization layer form a second coil, and wherein the second coil is arranged within an inner space defined by the first coil.

In various embodiments, the first coil may include a plurality of loops, wherein each loop of the plurality of loops of the first coil may extend from the first metallization layer to the fourth metallization layer, wherein the second coil may include a plurality of loops, and wherein each loop of the plurality of loops of the second coil may extend from the second metallization layer to the third metallization layer.

In various embodiments, the first coil and the second coil may be arranged in such a way that a long axis of the first coil and a long axis of the second coil coincide.

In various embodiments, the first coil further may include a plurality of vias, and the second coil may further include another plurality of vias.

In various embodiments, the plurality of vias of the first coil may be electrically coupled to the portion of the first metallization layer and to the portion of the fourth metallization layer; and the plurality of vias of the second coil may be electrically coupled to the portion of the second metallization layer and to the portion of the third metallization layer.

In various embodiments, each of the portions of the first, second, third and fourth metallization layers may include a plurality of regions, wherein each loop of the first coil may be formed by one of the regions of the first metallization layer, one of the regions of the fourth metallization layer, and two vias of the plurality of vias of the first coil; and wherein each loop of the second coil may be formed by one of the regions of the second metallization layer, one of the regions of the third metallization layer, and two vias of the plurality of vias of the second coil.

In various embodiments, within each loop of the first coil, the region of the first metallization layer, the region of the fourth metallization layer, and the two vias of the plurality of vias of the first coil may be electrically coupled with each other, wherein, within each loop of the second coil, the region of the second metallization layer, the region of the third metallization layer, and the two vias of the plurality of vias of the second coil may be electrically coupled with each other, wherein the loops of the first coil may be electrically coupled with each other; and wherein the loops of the second coil may be electrically coupled with each other.

In various embodiments, the inductor may further include: an electrical connection electrically connecting the first coil and the second coil in such a way that a direction of a current in each loop of the first coil is parallel to a direction of a current in each loop of the second coil.

In various embodiments, the inductor may further include a fifth metallization layer disposed over the second metallization layer, and a sixth metallization layer disposed over the fifth metallization layer; wherein a portion of the fifth metallization layer and a portion of the sixth metallization layer may form a third coil; and wherein the third coil may be arranged within an inner space defined by the second coil.

In various embodiments, a method of forming an inductor for a semiconductor device is provided. The method may include: forming a structured first metallization layer over a first side of a carrier; forming a first insulation layer over the structured first metallization layer from the first side; forming a structured second metallization layer over the structured first metallization layer from the first side; forming a second insulation layer over the structured second metallization layer from the first side; forming a plurality of vias through the second insulation layer electrically contacting a portion of the second metallization layer; forming a structured third metallization layer over the structured second metallization layer from the first side; electrically contacting a portion of the third metallization layer with the plurality of vias, wherein the portion of the second metallization layer and the portion of the third metallization layer form a second coil; forming a third insulation layer over the structured third metallization layer from the first side; forming a plurality of vias through the first, the second, and the third insulation layer electrically contacting the structured first metallization layer; and forming a structured fourth metallization layer over the structured third metallization layer from the first side, wherein a portion of the fourth metallization layer electrically contacts the plurality of vias formed through the first, the second, and the third insulation layer, wherein the portion of the first metallization layer and the portion of the fourth metallization layer form a first coil, and wherein the second coil is arranged within an inner space defined by the first coil.

In various embodiments, a method of forming an inductor for a semiconductor device is provided. The method may include: forming a plurality of vias through a carrier; forming a structured third metallization layer over a first side of the carrier; forming a structured second metallization layer over a second side of the carrier, wherein the vias electrically couple a portion of the third metallization layer to a portion of the second metallization layer, and wherein the portion of the second metallization layer and the portion of the third metallization layer form a second coil; forming an insulation layer over the second and the third metallization layers; forming a first metallization layer over the second metallization layer from the second side of the carrier; forming a plurality of vias through the insulation layer and the carrier from the first side of the carrier, wherein the plurality of vias electrically contacts a portion of the first metallization layer; and forming a fourth metallization layer over the third metallization layer from the first side of the carrier, electrically contacting a portion of the fourth metallization layer with the plurality of vias formed through the first, the second, and the third insulation layer, wherein the portion of the first metallization layer and the portion of the fourth metallization layer form a first coil, and wherein the second coil is arranged within an inner space defined by the first coil.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims, and all changes which come within the meaning and range of equivalency of the claims are therefore intended to be embraced.

Various aspects of the disclosure are provided for devices, and various aspects of the disclosure are provided for methods. It will be understood that basic properties of the devices also hold for the methods and vice versa. Therefore, for sake of brevity, duplicate description of such properties may be omitted.

What is claimed is:

1. An inductor for a semiconductor device, comprising:
a plurality of structured metallization layers, wherein the plurality of structured metallization layers comprises at least a first metallization layer, a second metallization layer disposed over the first metallization layer, a third metallization layer disposed over the second metallization layer, and a fourth metallization layer disposed over the third metallization layer;
wherein a portion of the first metallization layer and a portion of the fourth metallization layer form a first coil;
wherein a portion of the second metallization layer and a portion of the third metallization layer form a second coil; and
wherein the second coil is arranged within an inner space defined by the first coil.

2. The inductor according to claim 1,
wherein the first coil comprises a plurality of loops;
wherein each loop of the plurality of loops of the first coil extends from the first metallization layer to the fourth metallization layer;
wherein the second coil comprises a plurality of loops; and
wherein each loop of the plurality of loops of the second coil extends from the second metallization layer to the third metallization layer.

3. The inductor according to claim 1,
wherein the first coil and the second coil are arranged in such a way that a long axis of the first coil and a long axis of the second coil coincide.

4. The inductor according to claim 1,
wherein the first coil further comprises a plurality of vias; and
wherein the second coil further comprises another plurality of vias.

5. The inductor according to claim 4,
wherein the plurality of vias of the first coil is electrically coupled to the portion of the first metallization layer and to the portion of the fourth metallization layer; and
wherein the plurality of vias of the second coil is electrically coupled to the portion of the second metallization layer and to the portion of the third metallization layer.

6. The inductor according to claim 4,
wherein each of the portions of the first, second, third and fourth metallization layers comprises a plurality of regions;
wherein each loop of the first coil is formed by one of the regions of the first metallization layer, one of the regions of the fourth metallization layer, and two vias of the plurality of vias of the first coil; and
wherein each loop of the second coil is formed by one of the regions of the second metallization layer, one of the regions of the third metallization layer, and two vias of the plurality of vias of the second coil.

7. The inductor according to claim 4,
wherein, within each loop of the first coil, the region of the first metallization layer, the region of the fourth metallization layer, and the two vias of the plurality of vias of the first coil are electrically coupled with each other;
wherein, within each loop of the second coil, the region of the second metallization layer, the region of the third metallization layer, and the two vias of the plurality of vias of the second coil are electrically coupled with each other;
wherein the loops of the first coil are electrically coupled with each other; and
wherein the loops of the second coil are electrically coupled with each other.

8. The inductor according to claim 2, further comprising:
an electrical connection electrically connecting the first coil and the second coil in such a way that a direction of a current in each loop of the first coil is parallel to a direction of a current in each loop of the second coil.

9. The inductor according to claim 1, further comprising
a fifth metallization layer disposed over the second metallization layer, and a sixth metallization layer disposed over the fifth metallization layer;
wherein a portion of the fifth metallization layer and a portion of the sixth metallization layer form a third coil; and
wherein the third coil is arranged within an inner space defined by the second coil.

10. A method of forming an inductor for a semiconductor device, the method comprising:
forming a structured first metallization layer over a first side of a carrier;
forming a first insulation layer over the structured first metallization layer from the first side;
forming a structured second metallization layer over the structured first metallization layer from the first side;
forming a second insulation layer over the structured second metallization layer from the first side;
forming a plurality of vias through the second insulation layer electrically contacting a portion of the second metallization layer;
forming a structured third metallization layer over the structured second metallization layer from the first side,
electrically contacting a portion of the third metallization layer with the plurality of vias, and
wherein the portion of the second metallization layer and the portion of the third metallization layer form a second coil;
forming a third insulation layer over the structured third metallization layer from the first side;
forming a plurality of vias through the first, the second, and the third insulation layer electrically contacting the structured first metallization layer; and
forming a structured fourth metallization layer over the structured third metallization layer from the first side,
electrically contacting a portion of the fourth metallization layer with the plurality of vias formed through the first, the second, and the third insulation layer,
wherein the portion of the first metallization layer and the portion of the fourth metallization layer form a first coil, and
wherein the second coil is arranged within an inner space defined by the first coil.

11. The method of claim 10,
wherein the first coil and the second coil are arranged in such a way that a long axis of the first coil and a long axis of the second coil coincide.

12. The method of claim 10,
wherein each of the portions of the first, second, third and fourth metallization layers comprises a plurality of regions;
wherein each loop of the first coil is formed by one of the regions of the first metallization layer, one of the regions of the fourth metallization layer, and two vias of the plurality of vias of the first coil; and
wherein each loop of the second coil is formed by one of the regions of the second metallization layer, one of the regions of the third metallization layer, and two vias of the plurality of vias of the second coil.

13. The method of claim 12, further comprising:
electrically connecting the first coil and the second coil in such a way that a direction of a current in each loop of the first coil is parallel to a direction of a current in each loop of the second coil.

14. The method of claim 10, further comprising:
forming a structured fifth metallization layer over the structured second metallization layer from the first side after forming the second insulation layer;
forming a fourth insulation layer over the structured fifth metallization layer from the first side;
forming a plurality of vias through the fourth insulation layer electrically contacting a portion of the fifth metallization layer;
forming a structured sixth metallization layer over the structured fifth metallization layer from the first side,
electrically contacting a portion of the sixth metallization layer with the plurality of vias formed through the fourth insulation layer, and
wherein the portion of the fifth metallization layer and the portion of the sixth metallization layer form a third coil;
forming a fifth insulation layer over the structured sixth metallization layer from the first side.

15. The method of claim 1,
wherein the carrier comprises at least one further semiconductor device.

16. A method of forming an inductor for a semiconductor device, the method comprising:
forming a plurality of vias through a carrier;
forming a structured third metallization layer over a first side of the carrier;
forming a structured second metallization layer over a second side of the carrier, wherein the vias electrically couple a portion of the third metallization layer to a portion of the second metallization layer, and
wherein the portion of the second metallization layer and the portion of the third metallization layer form a second coil;
forming an insulation layer over the second and the third metallization layers;
forming a first metallization layer over the second metallization layer from the second side of the carrier;
forming a plurality of vias through the insulation layer and the carrier from the first side of the carrier, wherein the plurality of vias electrically contacts a portion of the first metallization layer; and
forming a fourth metallization layer over the third metallization layer from the first side of the carrier, wherein a portion of the fourth metallization layer electrically contacts the plurality of vias,
wherein the portion of the first metallization layer and the portion of the fourth metallization layer form a first coil, and
wherein the second coil is arranged within an inner space defined by the first coil.

17. The method of claim 16,
wherein the first coil and the second coil are arranged in such a way that a long axis of the first coil and a long axis of the second coil coincide.

18. The method of claim 16,
wherein each of the portions of the first, second, third and fourth metallization layers comprises a plurality of regions;
wherein each loop of the first coil is formed by one of the regions of the first metallization layer, one of the regions of the fourth metallization layer, and two vias of the plurality of vias of the first coil; and
wherein each loop of the second coil is formed by one of the regions of the second metallization layer, one of the regions of the third metallization layer, and two vias of the plurality of vias of the second coil.

19. The method of claim 16, further comprising:
electrically connecting the first coil and the second coil in such a way that a direction of a current in each loop of the first coil is parallel to a direction of a current in each loop of the second coil.

20. The method of claim 16,
wherein the structured second metallization layer and the structured third metallization layer are formed at the same time.
